(19) United States
(12) Patent Application Publication
(10) Pub. No.: US 2007/0247959 A1
(43) Pub. Date: Oct. 25, 2007

(54) Semiconductor memory device

(75) Inventors: Naoki Yamada, Osaka (JP); Kenichi Origasa, Osaka (JP)

Correspondence Address: STEPTOE & JOHNSON LLP, 1330 CONNECTICUT AVE., NW, WASHINGTON, DC, 20036, US

(73) Assignee: Matsushita Electric Industrial Co., Ltd., Kadoma-shi (JP)

(21) Appl. No.: 11/785,006

(22) Filed: Apr. 13, 2007

(30) Foreign Application Priority Data
Apr. 21, 2006 (JP) 2006-117314

(51) Int. Cl. G11C 8/00; G11C 5/14

(52) U.S. Cl. 365/230.06; 365/189.09

(57) ABSTRACT

With a semiconductor memory device according to the invention, it is possible to perform level shift of a word driver by a change in voltage at a line for a word driver P-channel control signal connected to a P-channel transistor, without a change in size of the P-channel transistor and that of an N-channel transistor, even at a low voltage of output from a row decoder. Thus, it is possible to maintain a small size ratio between the N-channel transistor and the P-channel transistor.

### BACKGROUND OF THE INVENTION

(1) Field of the Invention

The present invention relates to a semiconductor memory device provided with a memory cell array including a plurality of memory cells. In the semiconductor memory device, the memory cell array is selectively driven by a word line selection circuit and a word line drive circuit, thereby storing data.

(2) Description of the Related Art

As a semiconductor memory device, conventionally, there has been typically used a dynamic random access memory (DRAM) provided with a memory cell array which includes a plurality of memory cells and stores data.

In such DRAM, the memory cell array is connected with a plurality of word lines. Each word line is connected with a plurality of memory selection transistors forming a word line selection circuit, and one of word drivers forming a word line drive circuit.

In the DRAM, when one of the word drivers is selected, a voltage VPP, which is higher than a voltage for driving a normal bit line or a voltage for driving a control circuit, is used as a word line voltage. As functions of such word driver, desirably, output from the word driver is asserted or negated at a high speed and, further, a circuit configuration of the word driver is small in area and low in power consumption.

Hereinafter, a description will be given of the aforementioned conventional semiconductor memory device (DRAM) with reference to the drawings (refer to, for example, JP2001-344969A).

FIG. 15 is a circuit diagram illustrating configurations of a word driver block and a row decoder in the conventional semiconductor memory device. As illustrated in FIG. 15, the word driver block and row decoder described herein include first to fourth word driver units 1501 to 1504, AND elements 1505, and inverters 1506.

Herein, the first to fourth word driver units 1501 to 1504 receive word line predecode signals XPW0 to XPW3, respectively. The first word driver unit 1501 is connected with a plurality of word lines WL(4n) (n=0 to 63). The second word driver unit 1502 is connected with a plurality of word lines WL(4n+1) (n=0 to 63). The third word driver unit 1503 is connected with a plurality of word lines WL(4n+2) (n=0 to 63). The fourth word driver unit 1504 is connected with a plurality of word lines WL(4n+3) (n=0 to 63).

The row decoder has 64 row decoder units arranged therein. Each row decoder unit includes the AND element 1505 and the inverter 1506 connected to an output end of the AND element 1505. The AND element 1505 has input ends connected to one of lines for row predecode signals XPA and one of lines for row predecode signals XPB. Herein, there are prepared 64 pairs of the row predecode signals XPA and the row predecode signals XPB without overlap.

The output end of the AND element 1505 is also connected to a line for a row decode signal ADn (n=0 to 63), and an output end of the inverter 1506 is connected to a line for a row decode signal /ADn (n=0 to 63). The row decode signals ADn and /ADn are transmitted to the first to fourth word driver units 1501 to 1504, respectively.

FIG. 16 illustrates a layout of word drivers in the conventional semiconductor memory device. The word driver unit 1501 includes 64 word drivers 1601 for driving the word lines WL(4n) (n=0 to 63). Similarly, the word driver unit 1502 includes 64 word drivers 1601 for driving the word lines WL(4n+1) (n=0 to 63), the word driver unit 1503 includes 64 word drivers 1601 for driving the word lines WL(4n+2) (n=0 to 63), and the word driver unit 1504 includes 64 word drivers 1601 for driving the word lines WL(4n+3) (n=0 to 63). Thus, the 256 word drivers 1601 are arranged such that the adjoining word drivers 1601 are connected to the different lines for the word line predecode signals XPW0 to XPW3.

FIG. 17 is a circuit diagram illustrating a configuration of the word driver in the conventional semiconductor memory device As illustrated in FIG. 17, the word driver described herein includes a level shifter 1701, a first-stage driver 1702, and second-stage drivers 1703.

The level shifter 1701 receives the word line predecode signal XPWm (m=0 to 3), and transmits output therefrom to the first-stage driver 1702. The first-stage driver 1702 transmits, as output therefrom, word line selection signals WD and /WD to each second-stage driver 1703. The second-stage driver 1703 has an output end connected to the word line WLn (n=0 to 255).

Next, a description will be given of operations of the aforementioned conventional semiconductor memory device. When the word line predecode signal XPWm is asserted, the word line selection signals WD and /WD are shifted to a level of a first power supply VPP for the DRAM and a level of aground, respectively, through the level shifter 1701 and the first-stage driver 1702. In addition, the row decoder receives the row predecode signal XPA and the row predecode signal XPB each of which is asserted, and generates the row decode signals ADn and/and which are asserted and negated, respectively.

In one operation, only one of the second-stage drivers 1703 has a state where the word line selection signals WD and /WD are shifted to the level of the first power supply VPP for the DRAM and the level of the ground, respectively, and the row decode signals ADn and /ADn are asserted and negated, respectively. Thus, a potential at the selected word line WLn connected to the relevant second-stage driver 1703 is shifted to the level of the first power supply VPP for the DRAM, and potentials at the remaining non-selected word lines WLn are shifted to the level of the ground.

In the aforementioned conventional configuration, however, the level shifter 1701 cannot be operated if a potential at a second power supply VDD for the DRAM becomes low. The reason therefor is as follows. That is, if the potential at the second power supply VDD for the DRAM becomes low, a voltage to be applied to a gate of an N-channel transistor in the level shifter becomes low, resulting in deterioration of performance of the N-channel transistor.

In order to compensate for the low gate voltage, if a size ratio between an N-channel transistor and a P-channel transistor (N/P size ratio) is made larger, it is possible to perform level shift even at a low voltage. However, if the N/P size ratio is made larger, an operating speed when the N-channel transistor is turned off while the P-channel transistor is turned on becomes low. The reason therefor is as follows: a load applied onto the P-channel transistor becomes large.

Consequently, it is difficult for the level shifter in the conventional semiconductor memory device to achieve a high-speed operation and a low-power supply voltage operation.

### SUMMARY OF THE INVENTION

The present invention is made to solve the aforementioned conventional problems. It is an object of the present invention to provide a semiconductor memory device capable of realizing a small circuit configuration of a word driver, performing high-speed level shift of output from the word driver even at a low power supply voltage, and achieving further reduction in power consumption.

In order to accomplish this object, according to the present invention, a semiconductor memory device includes: a memory cell array including a plurality of bit lines, a plurality of word lines, and a plurality of memory cells each arranged at an intersection of each bit line and each word line; a word driver block for turning on/off the plurality of word lines; and a row decoder for generating a row decode signal for designating the word line to be turned on by the word driver block. Herein, the word line designated by the row decode signal from the row decoder is turned on by the word driver block so that the memory cell corresponding to the designated wordline is activated. Further, for each word line, the word driver block connects a P-channel transistor and an N-channel transistor in series between a first power supply having a voltage higher than a voltage at the bit line and a ground, transmits a word driver P-channel control signal for controlling an operating status of the word driver block to a gate of the P-channel transistor, transmits a row decode signal from the row decoder to a gate of the N-channel transistor, and connects a node between the P-channel transistor and the N-channel transistor to the relevant word line.

The semiconductor memory device can perform level shift of the word driver by a change in voltage of the word driver P-channel control signal from the P-channel transistor, without a change in size of the P-channel transistor and that of the N-channel transistor of the word driver, even at a lower voltage of output from the row decoder. Thus, it is possible to maintain a small size ratio between the N-channel transistor and the P-channel transistor.

According to the present invention, the node between the P-channel transistor and the N-channel transistor is connected to the relevant word line through an inverter. Therefore, such inverter serves as a driver at a final stage. As a result, it is possible to make a size of the P-channel transistor and that of the N-channel transistor small. This brings not only reduction in area, but also reduction of a load applied onto the word driver P-channel control power supply.

Herein, if an even number of inverters are provided, a memory cell can use a P-channel transistor. On the other hand, if an odd number of inverters are provided, such memory cell can use an N-channel transistor.

According to the present invention, the semiconductor memory device further includes a word driver P-channel control power supply supplying the word driver P-channel control signal to the word driver block so as to allow the word driver block to transmit the word driver P-channel control signal to the gate of the P-channel transistor. Herein, the word driver P-channel control power supply supplies, as the word driver P-channel control signal, a voltage lower than that from the first power supply to the word driver block. Thus, it is possible to prevent non-selected word lines from floating.

According to the present invention, the word driver P-channel control power supply switches, as the word driver P-channel control signal, between a voltage from the word driver P-channel control power supply when the designated word line is turned off and a voltage lower than the voltage from the word driver P-channel control power supply when the designated word line is turned on. Thus, it is possible to increase performance of the P-channel transistor in the word driver upon activation of the word line, thereby activating the word line at a higher speed.

According to the present invention, the word driver P-channel control power supply switches, as the word driver P-channel control signal of the word driver block selected in accordance with a block selection signal, between the voltage from the word driver P-channel control power supply when the designated word line is turned off and the voltage lower than the voltage from the word driver P-channel control power supply when the designated word line is turned on, and the word driver P-channel control signal of the non-selected word driver block from the block selection signal constantly has a voltage equal to the voltage from the word driver P-channel control power supply. Thus, it is possible to reduce a load applied onto the word driver P-channel control power supply.

According to the present invention, the word driver P-channel control power supply has a voltage lower than a difference in absolute value between the voltage from the first power supply and a threshold voltage at the P-channel transistor. Thus, it is possible to reduce an influence of coupling exerted on a non-selected word line adjoining to the selected word line.

According to the present invention, the word driver P-channel control power supply has an adjustable voltage. Thus, it is possible to set the voltage from the word driver P-channel control power supply at an optimal value with high accuracy.

According to the present invention, the word driver P-channel control power supply switches, as the word driver P-channel control signal, between the voltage from the word driver P-channel control power supply on standby and the voltage lower than the voltage from the word driver P-channel control power supply when the designated word line is turned on and, then, the voltage from the word driver P-channel control power supply before the designated word line is turned off. Thus, it is possible to reduce an amount of electric currents flowing through the word driver.

According to the present invention, the word driver P-channel control power supply has a voltage set at a level of a ground. Thus, it is possible to generate a voltage lower than the voltage from the word driver P-channel control power supply without provision of an additional circuit.

According to the present invention, as described above, it is possible to perform level shift of a word driver by a change in voltage of a word driver P-channel control signal from a P-channel transistor, without a change in size of the P-channel transistor and that of an N-channel transistor of the word driver, even at a low voltage of output from a row decoder. Thus, it is possible to maintain a small size ratio between the N-channel transistor and the P-channel transistor.

Therefore, it is possible to realize a small circuit configuration of a word driver, perform high-speed level shift of output from the word driver even at a low power supply voltage, and achieve further reduction in power consumption.

As a result, it is possible to realize a high-speed operation and a low-power supply voltage operation.

A conventional word driver has a complicated circuit configuration due to two lines separated for row decode signals in order to reduce a layout area of a row decoder. According to the present invention, however, it is possible to improve design freedom as long as a row decoder can properly select a word driver in accordance with an address signal with a change in circuit configuration of the word driver.

### BRIEF DESCRIPTION OF THE DRAWINGS

FIG. 1 illustrates a configuration of a semiconductor chip on which a semiconductor memory device according to a first embodiment of the present invention is mounted;

FIG. 2 is a block diagram illustrating a configuration of the semiconductor memory device according to the first embodiment;

FIG. 3 is a circuit diagram illustrating an address latch forming the semiconductor memory device according to the first embodiment;

FIG. 4 is a circuit diagram illustrating a row controller forming the semiconductor memory device according to the first embodiment;

FIG. 5 is a circuit diagram illustrating a memory cell array and a sense amplifier block each forming the semiconductor memory device according to the first embodiment;

FIG. 6 is a circuit diagram illustrating a word driver block and a row decoder each forming the semiconductor memory device according to the first embodiment;

FIG. 7 is a circuit diagram illustrating an LP generation circuit forming the semiconductor memory device according to the first embodiment;

FIG. 8 is a circuit diagram illustrating a resistor block in the LP generation circuit forming the semiconductor memory device according to the first embodiment;

FIG. 9 is a timing chart showing operations of the semiconductor memory device according to the first embodiment;

FIG. 10 is a circuit diagram illustrating an LP generation circuit forming a semiconductor memory device according to a second embodiment of the present invention;

FIG. 11 is a timing chart showing operations of the semiconductor memory device according to the second embodiment;

FIG. 12 is a circuit diagram illustrating a word driver block and a row decoder each forming a semiconductor memory device according to a third embodiment of the present invention;

FIG. 13 is a circuit diagram illustrating a resistor block in an LP generation circuit forming a semiconductor memory device according to a fourth embodiment of the present invention;

FIG. 14 illustrates a configuration of a semiconductor chip on which the semiconductor memory device according to the fourth embodiment is mounted;

FIG. 15 is a circuit diagram illustrating a word driver block and a row decoder each forming a conventional semiconductor memory device;

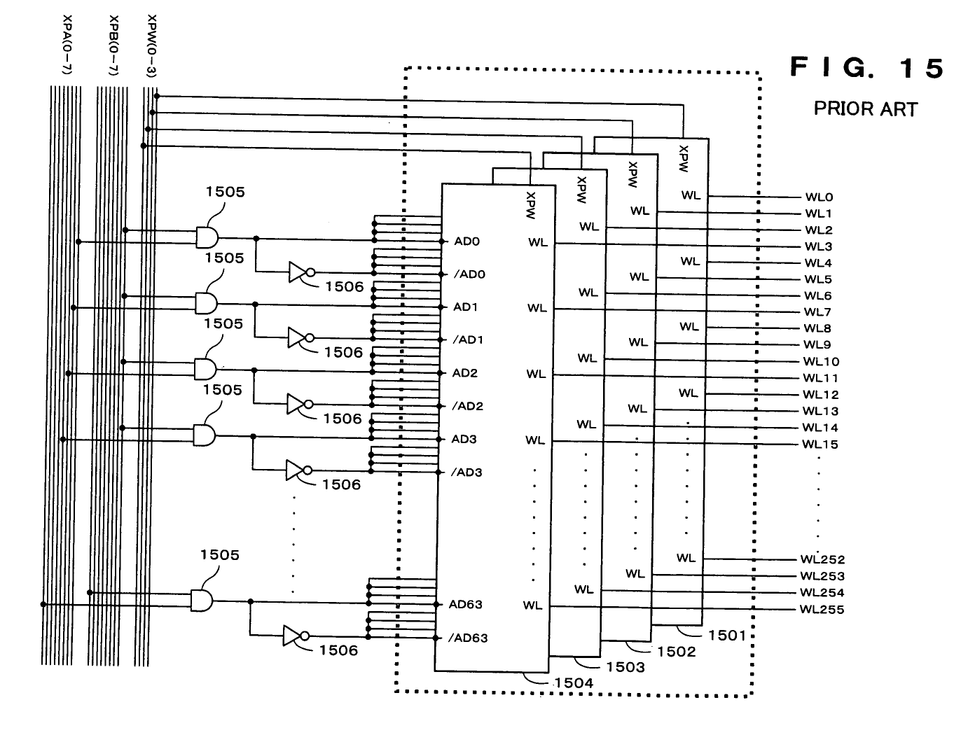

FIG. 16 illustrates a layout of word drivers forming the conventional semiconductor memory device; and

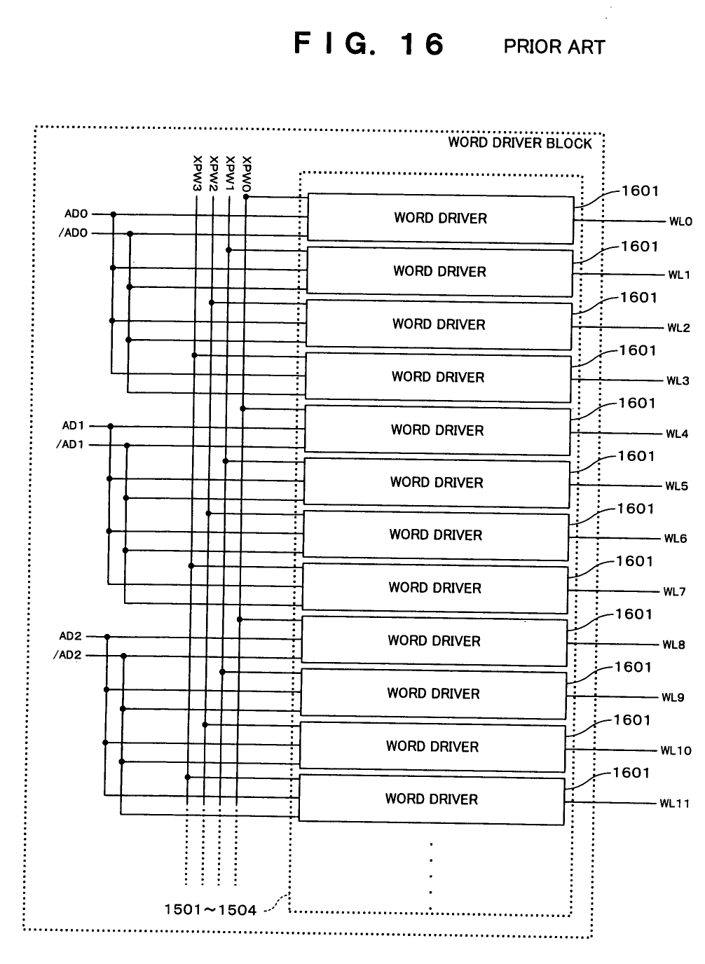

FIG. 17 is a circuit diagram illustrating the word driver forming the conventional semiconductor memory device.

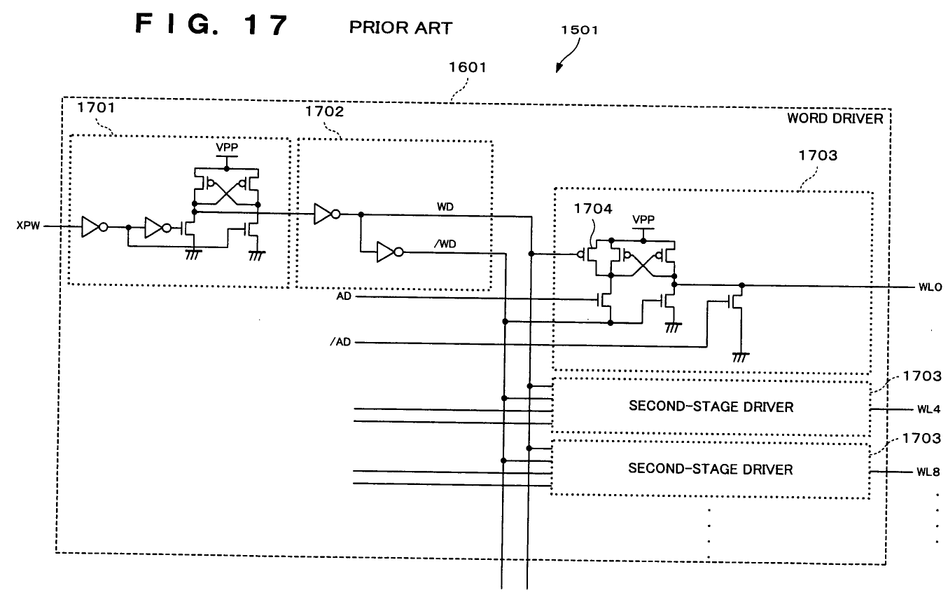

### DESCRIPTION OF THE PREFERRED EMBODIMENTS

Hereinafter, a detailed description will be given of preferred embodiments of the present invention with reference to the drawings.

### First Embodiment

First, a description will be given of a semiconductor memory device according to the first embodiment of the present invention.

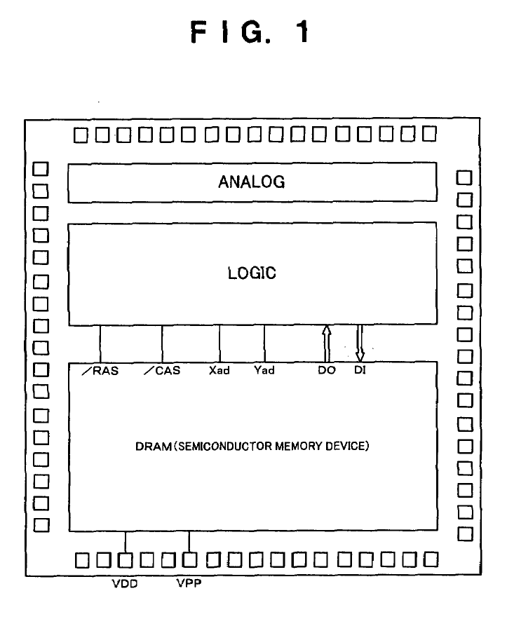

FIG. 1 illustrates a configuration of a semiconductor chip in a semiconductor integrated circuit on which the semiconductor memory device according to the first embodiment is mounted. In the following description, a dynamic random access memory (DRAM) illustrated in FIG. 1 is used as an example of the semiconductor memory device.

In the semiconductor integrated circuit, as illustrated in FIG. 1, a logic circuit and an analog circuit are mounted together with the DRAM on the semiconductor chip. In addition, a plurality of pads are provided along an outer periphery of the semiconductor chip, and are electrically connected to the DRAM, the logic circuit and the analog circuit. In the plurality of pads, there are included a pad for connection between the DRAM and a first power supply VPP and a pad for connection between the DRAM and a second power supply VDD. Herein, a voltage supplied from the first power supply VPP to the DRAM is higher than a voltage supplied from the second power supply VDD to the DRAM.

The DRAM has a data input end DIn and a data output end DOn each connected to the logic circuit. The logic circuit transmits, as control signals, a row address strobe signal /RAS and a column address strobe signal /CAS to the DRAM. The logic circuit also transmits, as address signals, a row address signal Xad and a column address signal Yad to the DRAM.

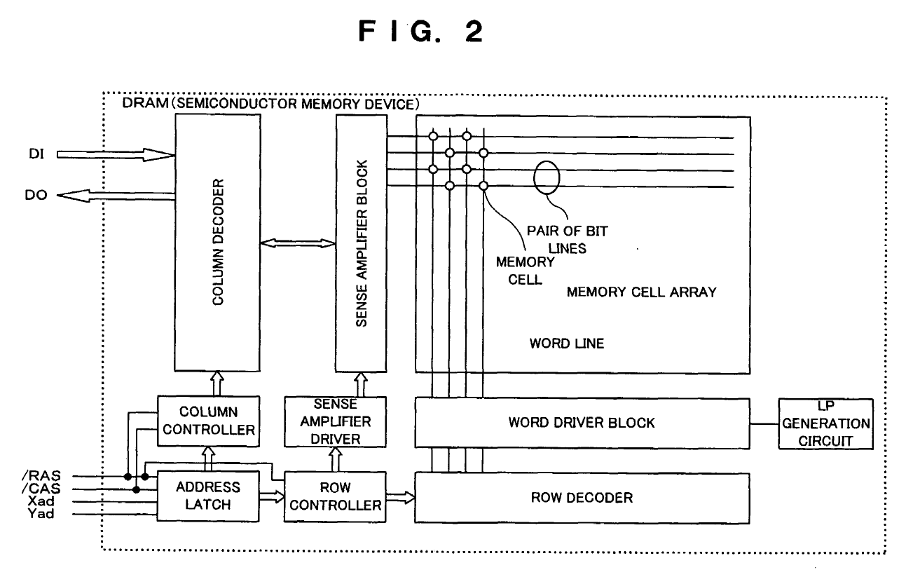

FIG. 2 is a block diagram illustrating a configuration of the DRAM serving as the semiconductor memory device according to the first embodiment. As illustrated in FIG. 2, the DRAM includes a memory cell array, a word driver block, a row decoder, a sense amplifier block, a column decoder, a sense amplifier driver, a row controller, a column controller and an address latch.

The memory cell array includes a plurality of pairs of bit lines, a plurality of word lines, and a plurality of memory cells each arranged at an intersection of each pair of bit lines and each word line. The plurality of word lines are connected to the word driver block. The plurality of pairs of bit lines are connected to the sense amplifier block.

The word driver block is connected to the row decoder. The row decoder is connected to the row controller. The row controller is connected to the sense amplifier driver and a line for the row address strobe signal /RAS. The sense amplifier driver is connected to the sense amplifier block.

The sense amplifier block is connected to the column decoder. The column decoder is connected to the data input end DIn and the data output end DOn. The column decoder is also connected to the column controller. The column controller is connected to the line for the row address strobe signal /RAS, a line for the column address strobe signal /CAS, and the address latch.

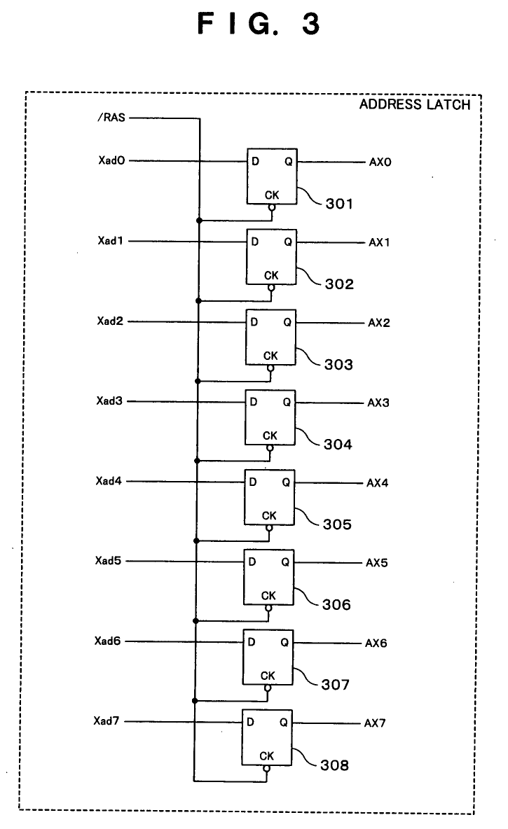

FIG. 3 is a circuit diagram illustrating a configuration of the address latch in the first embodiment. As illustrated in FIG. 3, the address latch includes D flip-flops 301 to 308. In the first embodiment, the address latch receives the row address signal Xadn of eight bits. That is, the D flip-flops 301 to 308 have terminals D connected to lines for the row address signals Xad0 to Xad7, respectively.

The D flip-flops 301 to 308 have output terminals Q connected to lines for row address latch signals AX0 to AX7, respectively. The D flip-flops 301 to 308 also have terminals CK connected to the line for the row address strobe signal /RAS.

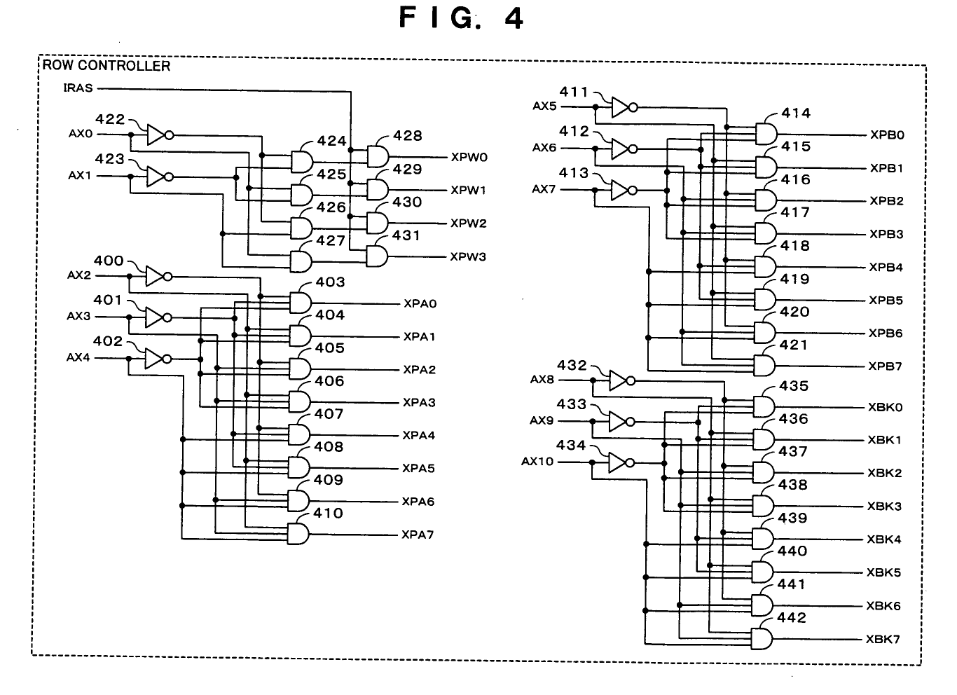

FIG. 4 is a circuit diagram illustrating a configuration of the row controller in the first embodiment. The row controller receives a word line activation signal IRAS, and the row address latch signals AX0 to AX7. The row controller includes first to third inverters 400 to 402, fourth and fifth inverters 422 and 423, sixth to eighth inverters 411 to 413, ninth to eleventh inverters 432 to 434, first to eighth AND elements 403 to 410, ninth to sixteenth AND elements 424 to 431, seventeenth to twenty-fourth AND elements 414 to 421, and twenty-fifth to thirty-second AND elements 435 to 442.

The first to third inverters 400 to 402 receive the row address latch signals AX2 to AX4, respectively. The fourth and fifth inverters 422 and 423 receive the row address latch signals AX0 and AX1, respectively. The sixth to eighth inverters 411 to 413 receive the row address latch signals AX5 to AX7, respectively. The ninth to eleventh inverters 432 to 434 receive the row address latch signals AX8 to AX10, respectively.

The first AND element 403 receives output from the first to third inverters 400 to 402. The first AND element 403 generates a row predecode signal XPA0. The second AND element 404 receives the row address latch signal AX2, and the output from the second and third inverters 401 and 402. The second AND element 404 generates a row predecode signal XPA1. The third AND element 405 receives the row address latch signal AX3, and the output from the first and third inverters 400 and 402. The third AND element 405 generates a row predecode signal XPA2. The fourth AND element 406 receives the row address latch signals AX2 and AX3, and the output from the third inverter 402. The fourth AND element 406 generates a row predecode signal XPA3. The fifth AND element 407 receives the row address latch signals AX4, and the output from the first and second inverters 400 and 401. The fifth AND element 407 generates a row predecode signal XPA4. The sixth AND element 408 receives the row address latch signals AX2 and AX4, and the output from the second inverter 401. The sixth AND element 408 generates a row predecode signal XPA5. The seventh AND element 409 receives the row address latch signals AX3 and AX4, and the output from the first inverter 400. The seventh AND element 409 generates a row predecode signal XPA6. The eighth AND element 410 receives the row address latch signals AX2 to AX4. The eighth AND element 410 generates a row predecode signal XPA7.

The seventeenth AND element 414 receives output from the sixth to eighth inverters 411 to 413. The seventeenth AND element 414 generates a row predecode signal XPB0. The eighteenth AND element 415 receives the row address latch signal AX5, and the output from the seventh and eighth inverters 412 and 413. The eighteenth AND element 415 generates a row predecode signal XPB1. The nineteenth AND element 416 receives the row address latch signal AX6, and the output from the sixth and eighth inverters 411 and 413. The nineteenth AND element 416 generates a row predecode signal XPB2. The twentieth AND element 417 receives the row address latch signals AX5 and AX6, and the output from the eighth inverter 413. The twentieth AND element 417 generates a row predecode signal XPB3. The twenty-first AND element 418 receives the row address latch signal AX7, and the output from the sixth and seventh inverters 411 and 412. The twenty-first AND element 418 generates a row predecode signal XPB4. The twenty-second AND element 419 receives the row address latch signals AX5 and AX7, and the output from the seventh inverter 412. The twenty-second AND element 419 generates a row predecode signal XPB5. The twenty-third AND element 420 receives the row address latch signals AX6 and AX7, and the output from the sixth inverter 411. The twenty-third AND element 420 generates a row predecode signal XPB6. The twenty-fourth AND element 421 receives the row address latch signals AX5 to AX7. The twenty-fourth AND element 421 generates a row predecode signal XPB7.

The ninth AND element 424 receives output from the fourth and fifth inverters 422 and 423. The thirteenth AND element 428 receives output from the ninth AND element 424, and the word line activation signal IRAS. The thirteenth AND element 428 generates a word line predecode signal XPW0. The tenth AND element 425 receives the row address latch signal AX0, and the output from the fifth inverter 423. The fourteenth AND element 429 receives output from the tenth AND element 425, and the word line activation signal IRAS. The fourteenth AND element 429 generates a word line predecode signal XPW1. The eleventh AND element 426 receives the row address latch signal AX1, and the output from the fourth inverter 422. The fifteenth AND element 430 receives output from the eleventh AND element 426, and the word line activation signal IRAS. The fifteenth AND element 430 generates a word line predecode signal XPW2. The twelfth AND element 427 receives the row address latch signals AX0 and AX1. The sixteenth AND element 431 receives output from the twelfth AND element 427, and the word line activation signal IRAS. The sixteenth AND element 431 generates a word line predecode signal XPW3.

The twenty-fifth AND element 435 receives output from the ninth to eleventh inverters 432 to 434. The twenty-fifth AND element 435 generates a block selection signal XBK0. The twenty-sixth AND element 436 receives the row address latch signal AX8, and the output from the tenth and eleventh inverters 433 and 434. The twenty-sixth AND element 436 generates a block selection signal XBK1. The twenty-seventh AND element 437 receives the row address latch signal AX9, and the output from the ninth and eleventh inverters 432 and 434. The twenty-seventh AND element 437 generates a block selection signal XBK2. The twenty-eighth AND element 438 receives the row address latch signals AX8 and AX9, and the output from the eleventh inverter 434. The twenty-eighth AND element 438 generates a block selection signal XBK3. The twenty-ninth AND element 439 receives the row address latch signal AX10, and the output from the ninth and tenth inverters 432 and 433. The twenty-ninth AND element 439 generates a block selection signal XBK4. The thirtieth AND element 440 receives the row address latch signals AX8 and AX10, and the output from the tenth inverter 433. The thirtieth AND element 440 generates a block selection signal XBK5. The thirty-first AND element 441 receives the row address latch signals AX9 and AX10, and the output from the ninth inverter 432. The thirty-first AND element 441 generates a block selection signal XBK6. The thirty-second AND element 442 receives the row address latch signals AX8 to AX10. The thirty-second AND element 442 generates a block selection signal XBK7.

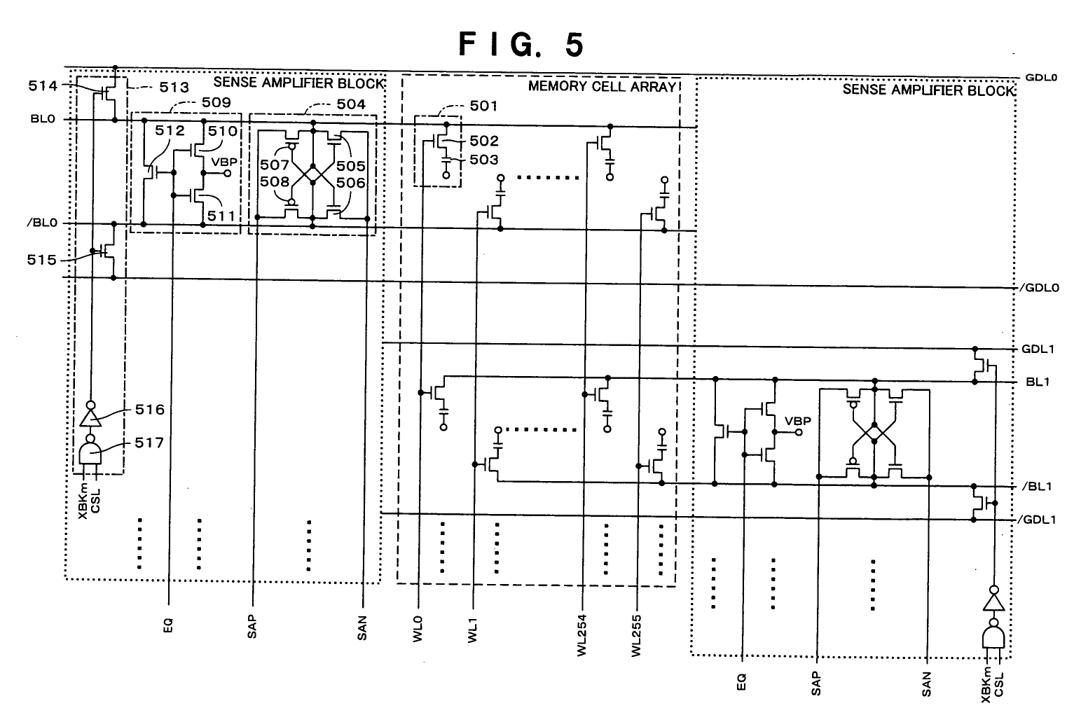

FIG. 5 is a circuit diagram illustrating configurations of the memory cell array and the sense amplifier block in the first embodiment. As illustrated in FIG. 5, the memory cell array includes a plurality of word lines WLn (n=0 to 255 in the first embodiment), a plurality of pairs of bit lines BLn and /BLn (n=0 to 1023 in the first embodiment) intersecting the plurality of word lines WLn, and a plurality of memory cells 501 each arranged at an intersection of each word line and each pair of bit lines.

Each memory cell 501 includes an N-channel transistor 502 and a capacitor 503. The N-channel transistor 502 has a gate connected to the word line WLn, a source connected to the bit line BLn, and a drain connected to a first node of the capacitor 503. A second node of the capacitor 503 is applied with a voltage which is a half of a voltage from the second power supply VDD for the DRAM.

The sense amplifier block includes a plurality of sense amplifiers 504, a plurality of precharge circuits 509 and a plurality of data transfer drivers 513.

Each sense amplifier 504 includes N-channel transistors 505 and 506, and P-channel transistors 507 and 508. The N-channel transistor 505 has a gate connected to the bit line /BLn, a source connected to a sense amplifier ground SAN, and a drain connected to the bit line BLn. The N-channel transistor 506 has a gate connected to the bit line BLn, a source connected to the sense amplifier ground SAN, and a drain connected to the bit line /BLn. The P-channel transistor 507 has a gate connected to the bit line /BLn, a source connected to a sense amplifier power supply SAP, and a drain connected to the bit line BLn. The P-channel transistor 508 has a gate connected to the bit line BLn, a source connected to the sense amplifier power supply SAP, and a drain connected to the bit line /BLn.

Each precharge circuit 509 includes N-channel transistors 510 to 512. The N-channel transistor 510 has a gate connected to a line for a bit line precharge signal EQ, a source connected to the bit line BLn, and a drain connected to a bit line precharge power supply VBP. The N-channel transistor 511 has a gate connected to the line for the bit line precharge signal EQ, a source connected to the bit line /BLn, and a drain connected to the bit line precharge power supply VBP. The N-channel transistor 512 has a gate connected to the line for the bit line precharge signal EQ, a source connected to the bit line /BLn, and a drain connected to the bit line BLn.

Each data transfer driver 513 includes N-channel transistors 514 and 515 corresponding to the pair of bit lines BLn and /BLn, an inverter 516, and a NAND element 517. The N-channel transistor 514 has a gate connected to an output end of the inverter 516, a source connected to the bit line BLn, and a drain connected to a global data line GDLn. The N-channel transistor 515 has a gate connected to the output end of the inverter 516, a source connected to the bit line /BLn, and a drain connected to a global data line /GDLn. The NAND element 517 has an input end connected to a line for the block selection signal XBKm (m=0 to 7), and an input end connected to a line for a data transfer timing signal CSL. The NAND element 517 has an output end connected to an input end of the inverter 516.

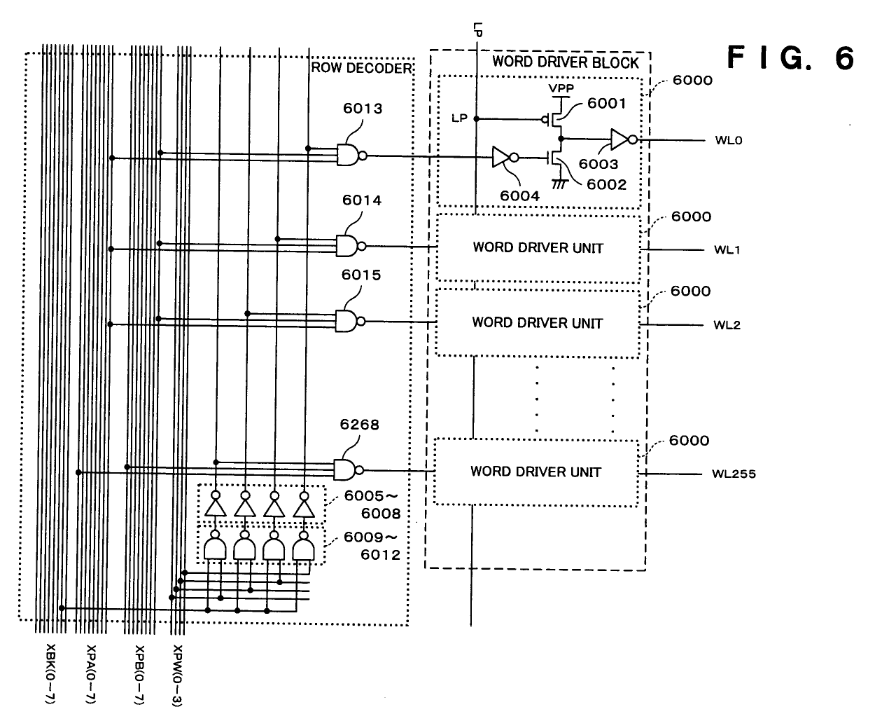

FIG. 6 is a circuit diagram illustrating configurations of the word driver block and the row decoder in the first embodiment. The word driver block includes word driver units 6000 connected to the word lines WLn on a one-by-one basis. Each word driver unit 6000 includes a P-channel transistor 6001, an N-channel transistor 6002, and inverters 6003 and 6004.

The P-channel transistor 6001 has a gate connected to a line for a word driver P-channel control signal LP, a source connected to the first power supply VPP for the DRAM, and a drain connected to an input end of the inverter 6003. The N-channel transistor 6002 has a gate connected to an output end of the inverter 6004, a source connected to a ground (ground potential), and a drain connected to the input end of the inverter 6003. The inverter 6003 has an output end connected to the word line WLn.

The row decoder includes inverters 6005 to 6008, NAND elements 6009 to 6012, and 3NAND elements 6013 to 6268.

The NAND element 6009 has an input end connected to a line for the word line predecode signal XPW0, an input end connected to the line for the block selection signal XBKm, and an output end connected to an input end of the inverter 6005. The NAND element 6010 has an input end connected to a line for the word line predecode signal XPW1, an input end connected to the line for the block selection signal XBKm, and an output end connected to an input end of the inverter 6006. The NAND element 6011 has an input end connected to a line for the word line predecode signal XPW2, an input end connected to the line for the block selection signal XBKm, and an output end connected to an input end of the inverter 6007. The NAND element 6012 has an input end connected to a line for the word line predecode signal XPW3, an input end connected to the line for the block selection signal XBKm, and an output end connected to an input end of the inverter 6008.

Each of the 3NAND elements 6013 to 6268 has input ends connected to one of lines for the row predecode signals XPA0 to XPA7, one of lines for the row predecode signals XPB0 to XPB7 and one of output ends of the inverters 6005 to 6009. The 3NAND elements 6013 to 6268 have output ends connected to input ends of the inverters 6004 of the word driver units 6000, respectively. Output from each of the 3NAND elements 6013 to 6268 is asserted by a voltage supplied from the second power supply VDD for the DRAM. Such output can be generated with a power supply similar to that of the logic circuit before a word driver receives the output.

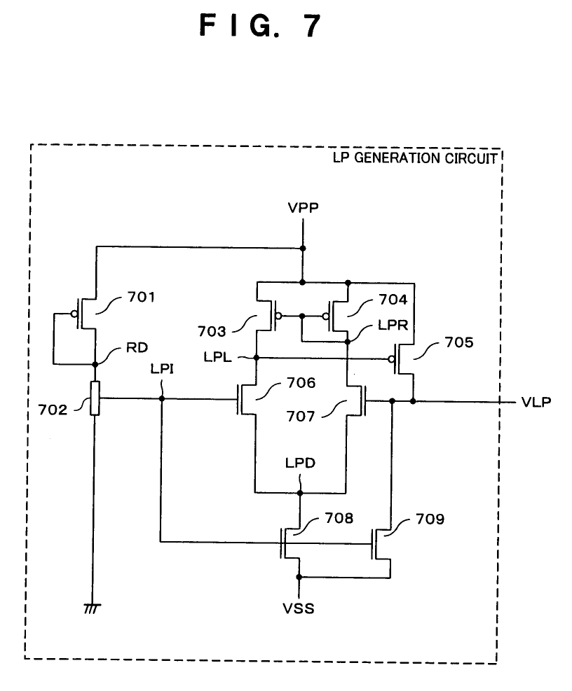

FIG. 7 is a circuit diagram illustrating a configuration of an LP generation circuit in the first embodiment. As illustrated in FIG. 7, the LP generation circuit described herein includes P-channel transistors 701, 703, 704 and 705, a resistor block 702, and N-channel transistors 706, 707, 708 and 709. The LP generation circuit generates a word driver P-channel control signal LP.

The P-channel transistor 701 has a gate and a drain each connected to a node RD, and a source connected to the first power supply VPP for the DRAM. The P-channel transistor 703 has a gate connected to a node LPR, a drain connected to a node LPL, and a source connected to the first power supply VPP for the DRAM. The P-channel transistor 704 has a gate and a drain each connected to the node LPR, and a source connected to the first power supply VPP for the DRAM. The P-channel transistor 705 has a gate connected to the node LPL, a source connected to the first power supply VPP for the DRAM, and a drain connected to a word driver P-channel control power supply VLP.

The N-channel transistor 706 has a gate connected to a node LPI, a drain connected to the node LPL, and a source connected to a node LPD. The N-channel transistor 707 has a gate connected to the word driver P-channel control power supply VLP, a drain connected to the node LPR, and a source connected to the node LPD. The N-channel transistor 708 has a gate connected to the node LPI, a drain connected to the node LPD, and a source connected to a ground (VSS). The N-channel transistor 709 has a gate connected to the node LPI, a drain connected to the word driver P-channel control power supply VLP, and a source connected to the ground (VSS).

The resistor block 702 is connected to the node LPI, the ground and the node RD.

In the first embodiment, a line for the word driver P-channel control signal LP is connected to the word driver P-channel control power supply VLP.

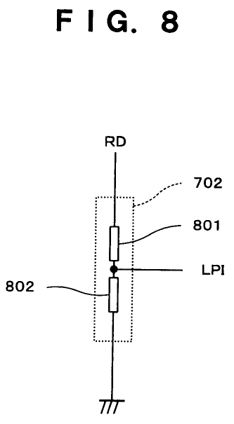

FIG. 8 is a circuit diagram illustrating a configuration of the resistor block in the first embodiment. As illustrated in FIG. 8, the resistor block described herein includes resistors 801 and 802. The resistor 801 has a first terminal connected to the node RD, and a second terminal connected to the node LPI. The resistor 802 has a first terminal connected to the node LPI, and a second terminal connected to the ground.

Next, a description will be given of operations of the aforementioned semiconductor memory device according to the first embodiment.

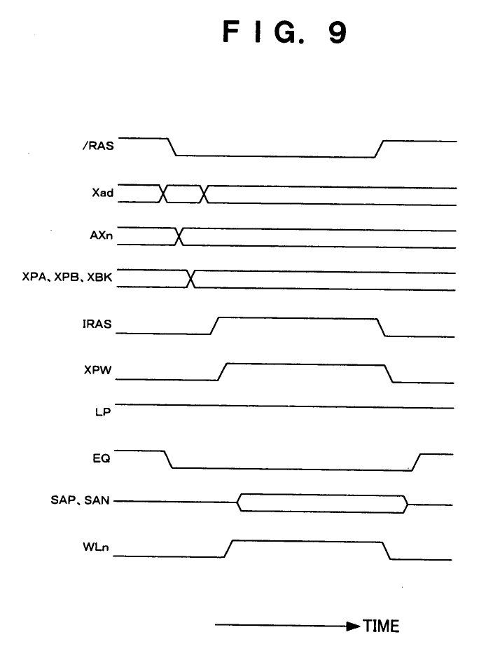

FIG. 9 is a timing chart showing the operations of the semiconductor memory device according to the first embodiment.

As shown in FIG. 9, at a falling edge of the row address strobe signal /RAS, the row address signals Xad are latched by the D flip-flops 301 to 308; thus, predetermined row addresses are allocated to the row address latch signals AX0 to AX10.

Next, by receiving the row address latch signals AX0 to AX10, the row controller generates the row predecode signals XPA, the row predecode signals XPB and the block selection signals XBK. Only one of the row predecode signals XPA0 to XPA7 is selected by the row address latch signals AX2 to AX4 and is asserted while the other row predecode signals are negated. Similarly, only one of the row predecode signals XPB0 to XPB7 is selected by the row address latch signals AX5 to AX7 and is asserted while the other row predecode signals are negated. Similarly, only one of the block selection signals XBK0 to XBK7 is selected by the row address latch signals AX8 to AX10 and is asserted while the other block selection signals are negated.

Also at the falling edge of the row address strobe signal /RAS, the bit line precharge signal EQ is negated in the sense amplifier driver. Herein, the precharge circuit 509 is deactivated. Also at the falling edge of the row address strobe signal /RAS, the word line activation signal IRAS is asserted. When the word line activation signal IRAS is asserted, only one of the word line selection predecode signals XPW0 to XPW3 is selected by the row address latch signals AX0 and AX1 and is asserted while the other word line selection predecode signals are negated.

The sense amplifier block receiving the asserted one of the row predecode signals XPB0 to XPB7 is activated. With regard to the memory cell array, the NAND elements 6013 to 6268 receive the row predecode signals XPA, the row predecode signals XPB and the word line selection predecode signals XPW each of which is asserted, and output from the NAND elements 6013 to 6268 is negated.

When the word driver unit 6000 is deactivated, the gate of the N-channel transistor 6002 is activated through the second inverter 6004, namely, is applied with a voltage from the second power supply VDD. Thus, the N-channel transistor 6002 is turned on to exceed the P-channel transistor 6001 in performance, and the first inverter 6003 is deactivated. As a result, the word line connected to the output end of the first inverter 6003 is activated, namely, is applied with a voltage from the first power supply VPP.

The number of word lines to be activated is only one, and the other word lines are deactivated (ground level). Herein, the word driver P-channel control signal LP has such a voltage that the N-channel transistor 6002 exceeds the P-channel transistor 6001 in performance upon selection of the word line. The N-channel transistor 502 of the memory cell 501 connected to the activated word line is turned on, so that a potential at the capacitor 503 is read onto the bit line BLn or /BLn connected to the memory cell 501.

Thereafter, a voltage from the sense amplifier power supply SAP becomes equal to the voltage from the second power supply VDD, and the sense amplifier ground SAN is grounded. Thus, all the sense amplifiers 504 are activated. Each of the activated sense amplifiers 504 charges the bit lines BLn and /BLn connected thereto at the potential of the second power supply VDD or the level of the ground, based on read potentials of the bit lines BLn and /BLn connected thereto.

Thereafter, the data transfer timing signal CSL from the column controller is asserted. Further, the N-channel transistors 514 and 515 of the data transfer driver 513 in the selected block are turned on. Thus, the bit line BLn is connected to the global data line GDLn while the bit line /BLn is connected to the global data line /GDLn.

On the other hand, as shown in FIG. 9, the word line activation signal IRAS is negated at the falling edge of the row address strobe signal /RAS. Thus, all the word line selection predecode signals XPW are negated, and the input to the word driver unit is asserted through the row decoder.

Thereafter, the input to the gate of the N-channel transistor is negated through the second inverter 6004, so that the N-channel transistor 6002 is turned off. Herein, the N-channel transistor 6002 is constantly turned off; therefore, the input to the first inverter 6003 is asserted, namely, is applied with the voltage from the first power supply VPP, and the output from the first inverter 6003 is negated. As a result, all the word lines WLn are deactivated (ground level).

At the falling edge of the row address strobe signal /RAS, each of the sense amplifier power supply SAP and the sense amplifier ground SAN has a potential equal to that of the bit line precharge power supply VBP.

Thereafter, the bit line precharge signal EQ is asserted in the sense amplifier driver, so that the precharge circuit 509 is activated. All the bit lines BLn and /BLn are precharged so as to have a potential equal to that at the bit line precharge power supply VBP.

The aforementioned circuit configuration produces the following advantages. That is, it is possible to perform level shift by a change in voltage at the line for the word driver P-channel control signal LP connected to the P-channel transistor 6001, without a change in size of the P-channel transistor 6001 and that of the N-channel transistor 6002, even at a low voltage of the output from the row decoder. Further, it is possible to realize a fast operation by an increase in size of the P-channel transistor 6001 and that of the N-channel transistor 6002.

Herein, the inverters 6003 and 6004 may not be provided or may be connected in series. When the inverter 6003 is connected such that the gate voltage at the N-channel transistor 6002 corresponding to the selected word line is activated, it is possible to impede the flow of electric current through the P-channel transistor 6001 and the N-channel transistor 6002. The provision of the inverter 6004 produces the following effect. That is, the inverter 6004 corresponding to a final driver can decrease the size of the P-channel transistor 6001 and that of the N-channel transistor 6002.

In a case where the transistor in the memory cell is an N-channel transistor as described in the first embodiment, an even number of inverters 6003 and 6004 to be connected are provided in total. On the other hand, in a case where the transistor in the memory cell is a P-channel transistor, an odd number of inverters 6003 and 6004 to be connected are provided in total.

Herein, the word driver P-channel control power supply VLP produces the following effect. That is, when the voltage from the word driver P-channel control power supply VLP is lower than that from the first power supply VPP, non-selected word lines can be prevented from floating. Further, the word driver P-channel control power supply VLP produces the following effect. That is, when the voltage from the word driver P-channel control power supply VLP is lower than a difference in absolute value between the voltage from the second power supply VDD and the threshold voltage at the P-channel transistor 6001, an influence of coupling exerted on adjoining word lines can be reduced.

A row decoder is not particularly limited to the aforementioned one as long as it receives a row address signal to generate a signal corresponding to a row address.

### Second Embodiment

Next, a description will be given of a semiconductor memory device according to the second embodiment of the present invention.

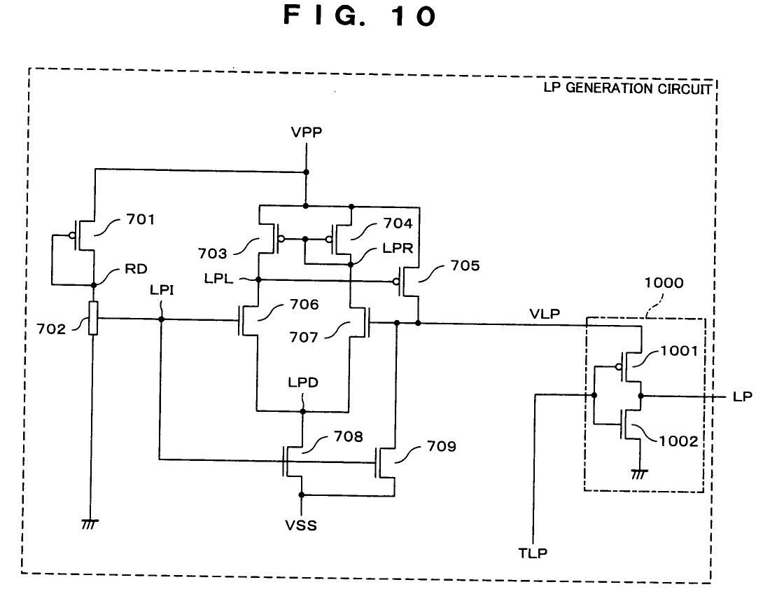

FIG. 10 is a circuit diagram illustrating a configuration of an LP generation circuit in the semiconductor memory device according to the second embodiment. As illustrated in FIG. 10, the LP generation circuit described herein is different from the LP generation circuit in the first embodiment in that an LP control driver 1000 is connected to the output end of the LP generation circuit illustrated in FIG. 7. The LP control driver 1000 includes a P-channel transistor 1001 and an N-channel transistor 1002.

The P-channel transistor 1001 has a gate connected to a line for a word driver P-channel control timing signal TLP, a source connected to a word driver P-channel control power supply VLP, and a drain connected to a line for a word driver P-channel control signal LP.

The N-channel transistor 1002 has a gate connected to the line for the word driver P-channel control timing signal TLP, a drain connected to the line for the word driver P-channel control signal LP, and a source connected to a ground.

In the configuration of the semiconductor memory device according to the second embodiment, circuits other than the LP generation circuit are similar to those described in the first embodiment and are denoted by the identical symbols to those in the first embodiment; therefore, a detailed description thereof will not be given here.

Next, a description will be given of operations of the aforementioned semiconductor memory device according to the second embodiment. In the first embodiment, the voltage from the word driver P-channel control power supply VLP connected to the LP generation circuit illustrated in FIG. 7 has a potential which is shifted in accordance with the operation of the word driver P-channel control power supply VLP. On the other hand, the LP generation circuit in the second embodiment is different from the LP generation circuit in the first embodiment only in an operation regarding the shift of the potential of the voltage from the word driver P-channel control power supply VLP. Therefore, a description will be given of only such operation herein. The other operations are similar to those described in the first embodiment; therefore, a detailed description thereof will not be given here.

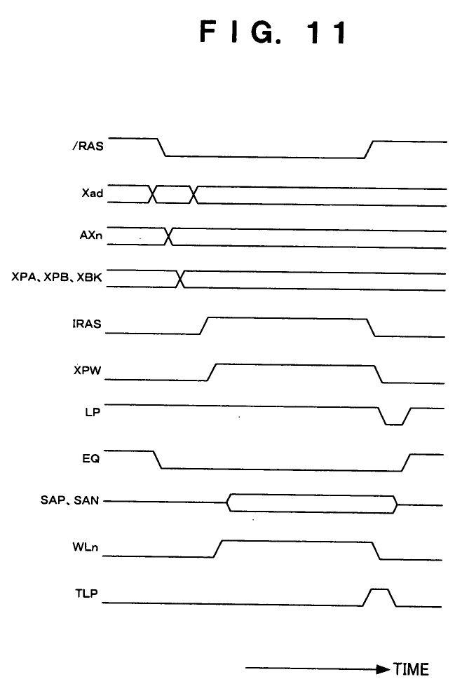

FIG. 11 is a timing chart showing the operations of the semiconductor memory device according to the second embodiment.

The word driver P-channel control timing signal TLP is negated normally, but is asserted concurrently with deactivation of a word line WLn. Thus, the N-channel transistor 1002 is turned on, and a potential of the word driver P-channel control signal LP becomes low (LOW level). Therefore, the performance of the P-channel transistor 1001 increases, so that the word line WLn can be deactivated at a higher speed.

During a period from the deactivation of the word line WLn to a start of a subsequent read/write operation, the word driver P-channel control timing signal TLP is negated. Thus, the N-channel transistor 1002 is turned off while the P-channel transistor 1001 is turned on, so that the word driver P-channel control signal LP is allowed to have a potential equal to the potential of the voltage from the word driver P-channel control power supply VLP again.

Herein, the timing of asserting the word driver P-channel control timing signal TLP is not necessarily consistent with the deactivation of the word line WLn as long as the word driver P-channel control timing signal TLP is asserted upon deactivation of the word line WLn. However, when the word driver P-channel control timing signal TLP is asserted concurrently with the deactivation of the word line WLn, an amount of electric currents flowing through a word driver unit can be minimized. In addition, when the voltage from the word driver P-channel control power supply VLP is lower than that from a first power supply VPP, non-selected word lines can be prevented from floating. Herein, the source of the N-channel transistor 1002 is not necessarily connected to the ground as long as it is applied a voltage lower than that from the word driver P-channel control power supply VLP. However, when the source of the N-channel transistor 1002 is connected to the ground, the word line can be deactivated at a higher speed without provision of an additional power supply circuit.

### Third Embodiment

Next, a description will be given of a semiconductor memory device according to the third embodiment of the present invention.

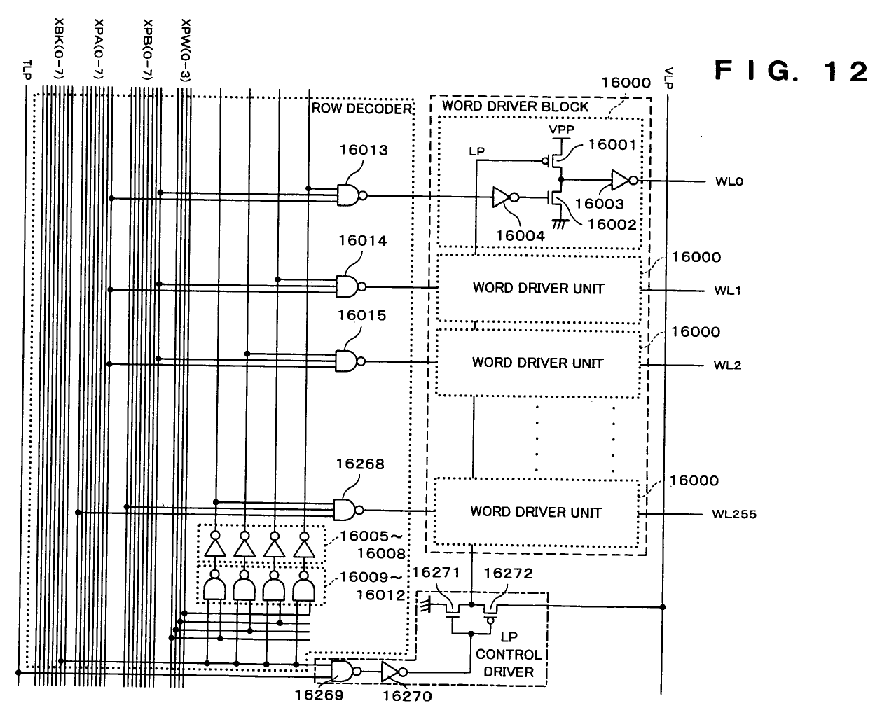

FIG. 12 is a circuit diagram illustrating configurations of a word driver block, a row decoder and an LP control driver in the semiconductor memory device according to the third embodiment. The word driver block includes word driver units 16000 connected to word lines on a one-by-one basis. Each word driver unit 16000 includes a P-channel transistor 16001, an N-channel transistor 16002, and inverters 16003 and 16004. The row decoder includes inverters 16005 to 16008, NAND elements 16009 to 16012, and 3NAND elements 16013 to 16268.

Connection forms of the N-channel transistor 16002, the inverters 16003 and 16004, the inverters 16005 to 16008, the NAND elements 16009 to 16012, and the 3NAND elements 16013 to 16268 are similar to those of the N-channel transistor 6002, the inverters 6003 and 6004, the inverters 6005 to 6008, the NAND elements 6009 to 6012, and the 3NAND elements 6013 to 6268 illustrated in FIG. 6, respectively. The P-channel transistor 16001 has a gate connected to a line for a word driver P-channel control signal LP from the LP control driver, a source connected to a first power supply VPP for the DRAM, and a drain connected to an input end of the inverter 16003.

The LP control driver includes a NAND element 16269, an inverter 16270, an N-channel transistor 16271 and a P-channel transistor 16272. The NAND element 16269 has input ends connected to a line for a block selection signal XBKm and a line for a word driver P-channel control timing signal TLP, respectively. The NAND element 16269 has an output end connected to an input end of the inverter 16270. The N-channel transistor 16271 has a gate connected to an output end of the inverter 16270, a drain connected to the line for the word driver P-channel control signal LP, and a source connected to a ground. The P-channel transistor 16272 has a gate connected to the output end of the inverter 16270, a drain connected to the line for the word driver P-channel control signal LP, and a source connected to a word driver P-channel control power supply VLP.

In the configuration of the semiconductor memory device illustrated in FIG. 12, circuits other than the word drive block, the row decoder and the LP control driver are similar to those described in the first embodiment and are denoted by the identical symbols to those in the first embodiment; therefore, a detailed description thereof will not be given here.

Next, a description will be given of operations of the aforementioned semiconductor memory device according to the third embodiment.

The third embodiment is different from the first embodiment in that only a block in which a potential of the word driver P-channel control signal LP is selected, is shifted. The other operations in the third embodiment are similar to those described in the first embodiment; therefore, a detailed description will not be given here. In the third embodiment, the description of the operations is given with reference to FIG. 11.

Similarly to the second embodiment, the word driver P-channel control timing signal TLP is negated normally, but is asserted concurrently with deactivation of a word line WLn. Thus, only an LP control driver in a block selected by such assertion is activated.

When the LP control driver is activated, a voltage at the gate of the P-channel transistor 16001 is shifted from a level of a potential of the word driver P-channel control signal LP to a level of the ground. Thus, the wordline WLn can be deactivated at a higher speed.

During a period from the deactivation of the word line WLn to a start of a subsequent read/write operation, the word driver P-channel control timing signal TLP is negated. Thus, the gate voltage at the P-channel transistor 16001 is recharged to the word driver P-channel control signal LP.

When the word driver P-channel control signal LP is controlled for each block, a load to be applied onto the word driver P-channel control power supply VLP can be made smaller.

Herein, the timing of asserting the word driver P-channel control timing signal TLP is not necessarily consistent with the deactivation of the word line WLn as long as the word driver P-channel control timing signal TLP is asserted upon deactivation of the word line WLn. However, when the word driver P-channel control timing signal TLP is asserted concurrently with the deactivation of the word line WLn, an amount of electric currents flowing through a word driver can be minimized. In addition, when the voltage from the word driver P-channel control power supply VLP is lower than that from a first power supply VPP, non-selected wordlines can be prevented from floating. Herein, the source of the N-channel transistor 16271 is not necessarily connected to the ground as long as it is applied a voltage lower than that from the word driver P-channel control power supply VLP. However, when the source of the N-channel transistor 16271 is connected to the ground, the word line can be deactivated at a higher speed without provision of an additional power supply circuit.

### Fourth Embodiment

Next, a description will be given of a semiconductor memory device according to the fourth embodiment of the present invention. Herein, the fourth embodiment is different from the first embodiment in a circuit configuration of a resistor block and a configuration of a semiconductor chip in a semiconductor integrated circuit. In the fourth embodiment, the other configurations are similar to those described in the first embodiment and are denoted by the identical symbols to those in the first embodiment; therefore, a detailed description thereof will not be given here.

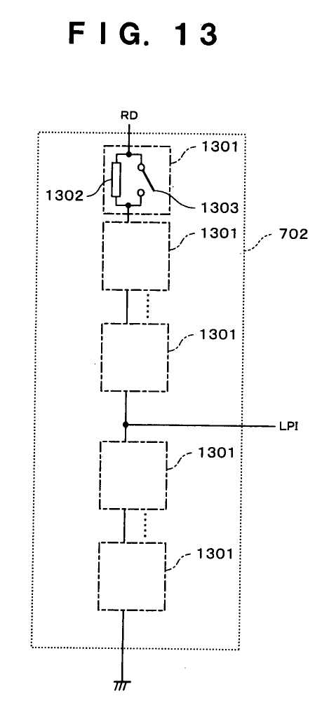

FIG. 13 is a circuit diagram illustrating the configuration of the resistor block in the semiconductor memory device according to the fourth embodiment. As illustrated in FIG. 13, the resistor block 702 described herein includes a plurality of resistance adjustment units 1301 connected in series between a node RD and a node LPI and connected in series between the node LPI and a ground. Each resistance adjustment unit 1301 includes a resistor 1302 and a switch 1303 which are connected in parallel.

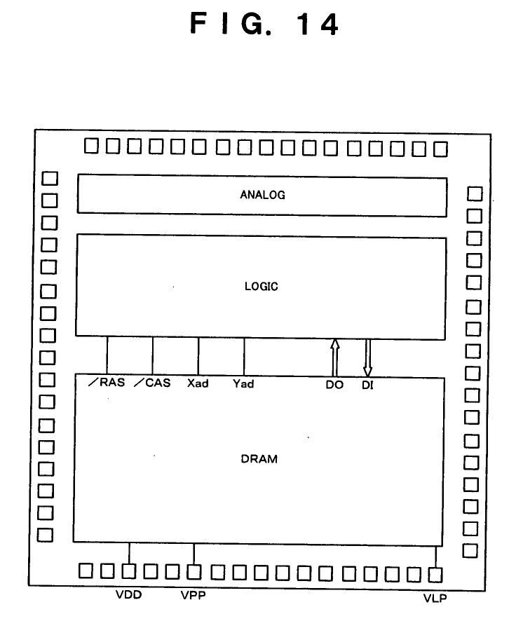

FIG. 14 is a block diagram illustrating the configuration of the semiconductor chip in the semiconductor integrated circuit on which the semiconductor memory device according to the fourth embodiment is mounted. In the semiconductor integrated circuit, as illustrated in FIG. 14, a word driver P-channel control power supply VLP is connected to one of pads provided on the semiconductor chip in order to adjust a voltage from the word driver P-channel control power supply VLP.

The voltage from the word driver P-channel control power supply VLP is adjusted to an optimal voltage by monitoring of the voltage through the pad for the word driver P-channel control power supply VLP.

In the fourth embodiment, thus, the voltage from the word driver P-channel control power supply VLP can be set at an optimal value with higher accuracy.

Also in the second and third embodiments, the aforementioned configuration can produce effects similar to those in the fourth embodiment.

What is claimed is:

1. A semiconductor memory device comprising:
a memory cell array including a plurality of bit lines, a plurality of word lines, and a plurality of memory cells each arranged at an intersection of each bit line and each word line;
a word driver block for turning on/off the plurality of word lines; and
a row decoder for generating a row decode signal for designating the word line to be turned on by the word driver block, wherein
the word line designated by the row decode signal from the row decoder is turned on by the word driver block so that the memory cell corresponding to the designated word line is activated, and
for each word line, the word driver block connects a P-channel transistor and an N-channel transistor in series between a first power supply and a ground, transmits a word driver P-channel control signal for controlling an operating status of the word driver block to a gate of the P-channel transistor, transmits a row decode signal from the row decoder to a gate of the N-channel transistor, and connects a node between the P-channel transistor and the N-channel transistor to the relevant word line.

2. The semiconductor memory device according to claim 1, wherein
the first power supply has a voltage higher than a voltage at the bit line.

3. The semiconductor memory device according to claim 2, wherein
the node between the P-channel transistor and the N-channel transistor is connected to the relevant word line through an inverter.

4. The semiconductor memory device according to claim 2, further comprising:
a word driver P-channel control power supply supplying the word driver P-channel control signal to the word driver block so as to allow the word driver block to transmit the word driver P-channel control signal to the gate of the P-channel transistor, wherein
the word driver P-channel control power supply supplies, as the word driver P-channel control signal, a voltage lower than that from the first power supply to the word driver block.

5. The semiconductor memory device according to claim 4, wherein
the word driver P-channel control power supply switches, as the word driver P-channel control signal, between a voltage from the word driver P-channel control power supply when the designated word line is turned off and a voltage lower than the voltage from the word driver P-channel control power supply when the designated word line is turned on.

6. The semiconductor memory device according to claim 5, wherein
the word driver P-channel control power supply switches, as the word driver P-channel control signal of the word driver block selected in accordance with a block selection signal, between the voltage from the word driver P-channel control power supply when the designated word line is turned off and the voltage lower than the voltage from the word driver P-channel control power supply when the designated word line is turned on, and
the word driver P-channel control signal of the non-selected word driver block from the block selection signal constantly has a voltage equal to the voltage from the word driver P-channel control power supply.

7. The semiconductor memory device according to claim 4, wherein
the word driver P-channel control power supply has a voltage lower than a difference in absolute value between the voltage from the first power supply and a threshold voltage at the P-channel transistor.

8. The semiconductor memory device according to claim 7, wherein
the word driver P-channel control power supply has an adjustable voltage.

9. The semiconductor memory device according to claim 5, wherein
the word driver P-channel control power supply switches, as the word driver P-channel control signal, between the voltage from the word driver P-channel control power supply on standby and the voltage lower than the voltage from the word driver P-channel control power supply when the designated word line is turned on and, then, the voltage from the word driver P-channel control power supply before the designated word line is turned off.

10. The semiconductor memory device according to claim 5, wherein
the word driver P-channel control power supply has a voltage set at a level of a ground.
